(19) United States
(12) Patent Application Publication
(10) Pub. No.: US 2020/0166582 A1
(43) Pub. Date: May 28, 2020

(54) METHOD FOR DETECTING A SELF-DISCHARGE DEFECT IN A BATTERY CELL

(71) Applicant: RENAULT s.a.s., Boulogne-Billancount (FR)

(72) Inventors: Michel MENSLER, Montigny Le Bretonneux (FR); Bruno DELOBEL, Issy Les Moulineaux (FR); Ana Lucia DRIEMEYER FRANCO, Montigny Le Bretonneux (FR); Benoit ARSAC, Versailles (FR); Masato ORIGUCHI, Rambouillet (FR)

(73) Assignee: RENAULT s.a.s., Boulogne-Billancourt (FR)

(21) Appl. No.: 16/626,203

(22) PCT Filed: Jul. 17, 2018
(86) PCT No.: PCT/EP2018/069414

§ 371 Date: Feb. 10, 2020

(30) Foreign Application Priority Data
Jul. 19, 2017 (FR) 1756838

(51) Int. Cl. G01R 31/396; H02J 7/00; G01R 31/392; G01R 31/3842

(52) U.S. Cl. CPC G01R 31/396; H02J 7/0016; G01R 31/3842; H02J 7/005; G01R 31/392; H02J 7/0048

(57) ABSTRACT

Said method is used for detecting, in an electric storage battery (10) having a plurality of battery cells (1, 2, 3, 4), a self-discharge defect in a cell (1, 2, 3, 4), wherein: a charge balancing of the battery cells (1, 2, 3, 4) is at least partially carried out, a relaxation of the battery cells (1, 2, 3, 4) is performed, a charge balance during the balancing and relaxation (Σᵢ) of said cell (i) is calculated for each battery cell (i), and any self-discharge defects of said cell (i) are detected for each battery cell (i) depending on the charge balance calculated for said cell (i) during the balancing and relaxation (Σᵢ).

The invention relates to the control of an electric storage battery having a plurality of cells, particularly intended to be incorporated into an automotive vehicle.

Electrically propelled automotive vehicles comprise, notably, purely electrically propelled vehicles, hybrid vehicles, or rechargeable hybrid vehicles. Such vehicles are equipped with an electric storage battery having a large number of battery cells. These cells may be installed in series and/or in parallel.

As a general rule, the cells forming an electric storage battery have similar characteristics to one another. However, during the life of the battery, dispersions or differences may appear in these cells. For example, there may be a dispersion of the capacity of the cells, a dispersion of the resistance of the cells, or possibly, in a temporary way, a dispersion of the state of charge of the cells or a dispersion of the temperature of the cells. These dispersions result in a different degree of ageing for each cell of an electric storage battery and a dispersion of the state of health of the cells.

The electric storage battery as a whole is directly affected by the dispersions relating to its constituent cells, and particularly by the dispersions of the state of charge. In fact, as the difference in charge among the cells increases, the total usable capacity of the battery decreases.

The usual way of overcoming this problem is to carry out regular balancing of the cells. This balancing can be performed directly by a battery management system operating in an autonomous way. For example, the cell balancing may be dissipative, consisting in balancing the states of charge of the cells by discharging the cells into a resistance towards a target state of charge. By means of this solution, the dispersion of the state of loading may be kept below a threshold, thus limiting the fall in the total usable capacity of the battery.

However, this solution is not entirely satisfactory. In fact, the cells of an electric storage battery may encounter internal problems resulting in a self-discharge which increases rapidly over time. This self-discharge increases the dispersion of the state of charge among the battery cells. If the self-discharge becomes too great, the balancing system loses its effectiveness and eventually becomes incapable of compensating for the dispersion of the state of charge among the cells of the electric storage battery. This usually leads to a rapid and considerable fall in the capacity of the electric storage battery, or even a breakdown of a cell, resulting in a breakdown of the electric storage battery as a whole.

The document CN 105527583 describes a method of detecting self-discharge in a battery pack, wherein a self-discharge defect of a battery cell is detected if the voltage at the terminals of the cell varies significantly between two predefined instants. Although such a method may enable a self-discharge defect to be detected in a cell, it is still possible for self-discharge defects to go undetected and/or for false self-discharge defect warnings to be emitted. Thus there is a need for a more reliable method of detecting a self-discharge defect to be proposed.

Moreover, the method described in CN 105527583 requires a long relaxation time for the cells between the two instants of voltage measurement. Consequently the method can be used only during long periods of inactivity of the vehicle, for example while the vehicle is kept on a parking lot. Such pauses occur infrequently. The detection of a self-discharge defect is therefore delayed, or even impossible.

In view of the above, the object of the invention is to detect a self-discharge defect of a cell of an electric storage battery at an early stage, so as to avoid a dispersion of the state of charge among the cells.

For this purpose, a method is proposed for detecting, in an electric storage battery having a plurality of battery cells, a self-discharge defect in a cell, wherein:
a balancing of the charges of the battery cells is carried out, at least partially,
a relaxation of the battery cells is carried out,
a charge balance is calculated for each battery cell during the balancing and relaxation of said cell, and
the possible existence of any self-discharge defect of said cell is detected for each battery cell on the basis of the charge balance during the balancing and relaxation calculated for said cell. Thus a self-discharge defect of a cell is detected by analyzing the effectiveness of the balancing of the battery cells. This results in more reliable detection of any self-discharge defect in each of the cells of this battery.

Advantageously, for each battery cell, the charge balance during the balancing and relaxation of said cell is calculated with allowance for at least one magnitude chosen from among the charge to be balanced for said cell immediately before the start of balancing of said cell, the charge to be balanced for said cell immediately after the end of the relaxation of said cell, and the amount of charge discharged for said cell during the balancing.

Preferably, for any battery cell, the charge balance is calculated during the balancing and relaxation of said cell, using the following relationship:

Σᵢ=q_{i,bal}(t₂)+Δqᵢ(T)−q_{i,bal}(t₁)

where “Σ_{I}” denotes the charge balance during the balancing and relaxation of said cell,

“q_{i,bal}(t)” denotes the charge to be balanced for said cell at an instant t,

“Δqᵢ(T)” denotes the amount of charge discharged for said cell during an interval T,

“t₁” denotes an instant located immediately before the start of the balancing of said cell,

“t₂” denotes an instant located immediately after the end of the relaxation of said cell, and

“T” denotes the period during which the balancing of the charges of the cell has been executed.

In one embodiment, for each cell, the balancing comprises a step of calculating a charge to be balanced for said cell and a step of executing the balancing in which the amount of charge discharged for said cell is calculated, and the balancing step is continued as long as the charge to be balanced for said cell is strictly greater than the amount of charge discharged for said cell.

This embodiment, in which a projected charge to be balanced is compared with an amount of charge actually discharged, allows particularly precise balancing. The accuracy of the detection of a self-discharge defect is thus improved.

In another embodiment, for each cell, the balancing comprises a step of calculating a charge to be balanced for said cell and a step of calculating a balancing time of said cell on the basis of the calculated charge to be balanced for said cell, in which the balancing is executed during the calculated balancing time.

This embodiment, based on the calculation of a projected balancing time, requires relatively few calculation resources to detect a self-discharge defect.

Advantageously, for each cell, a charge to be balanced for said cell is calculated on the basis of at least one parameter chosen from among a state of charge of said cell, a state of charge of a target cell, a capacity of said cell, a capacity of a target cell, a state of health of said cell, a state of health of a target cell, a zero current voltage of said cell, a zero current voltage of a target cell, a nominal capacity of said cell and a nominal capacity of a target cell.

Preferably, for each cell, an amount of charge discharged for said cell during a period is calculated on the basis of at least one parameter chosen from among a balancing resistance, a voltage at the terminals of said cell at an instant within said period, a balancing current of the cells of the electric storage battery, and a nominal voltage of the cells of the electric storage battery.

In one embodiment, the presence of a self-discharge defect in a first battery cell is detected if, for any second battery cell other than the first battery cell, the charge to be balanced by said second cell immediately after the end of the relaxation of said second cell is strictly greater than the charge to be balanced by said second cell immediately before the start of the balancing of said second cell, and the amount of charge discharged by said second cell during the balancing and relaxation is other than zero.

Such an embodiment enables a self-discharge defect to be detected in the battery cell whose state of charge corresponds to a state of charge of a target cell.

For each cell, it is also possible to provide for the detection of the presence of a self-discharge defect in said cell if the calculated charge balance for said cell during the balancing and relaxation exceeds a strictly positive threshold, said threshold being determined on the basis of at least one error chosen from among an error on the charge to be balanced for said cell immediately before the start of the balancing of said cell, an error on the charge to be balanced for said cell immediately after the end of the relaxation of said cell, and an error on the amount of charge discharged for said cell during the balancing and relaxation.

By applying such a threshold it is possible to allow for sources of inaccuracy related to the electric storage battery which would prevent detection or which, conversely, would result in false detection.

Advantageously, for any cell, said threshold is determined on the basis of an error on the charge to be balanced for said cell, said error being calculated, for any instant, according to the following expression:

δq_{i,bal}=|Qᵢ·δSOCᵢ|+SOCᵢ·δQᵢ|+|Q_{target}·δSOC_{target}|+|SOC_{target}·δQ_{target}|

where “δq_{i,bal}” represents the error on the charge to be balanced by said cell at said instant,

“δSOCᵢ” represents the error on the state of charge of said cell,

“δQᵢ” represents the error on the charge of said cell,

“δSOCᵢ” represents the state of charge of said cell at said instant,

“Qᵢ” represents the charge of said cell at said instant,

“δSOC_{target}” represents the error on the state of charge of the target cell,

“δQ_{target}” represents the error on the charge of the target cell,

“SOC_{target}” represents the state of charge of the target cell at said instant, and

“Q_{target}” represents the charge of the target cell at said instant.

Preferably, for any cell, said threshold is determined on the basis of an error on the amount of charge discharged for said cell during an interval, said error being calculated using the following expression:

$$δΔ {q}_{i} ( T ) = \vert \frac{1}{{R}_{bal}^{2}} \cdot {\int }_{0}^{T} {V}_{i} ( τ ) d τ \cdot δ {R}_{bal} \vert$$

where “T” represents said interval,

“Δqᵢ(T)” represents the error on the amount of charge discharged for said cell during said interval,

“R_{bal}” represents the resistance used for the balancing, and

for any instant τ belonging to said interval, “Vᵢ(τ)” denotes the voltage measured at the terminals of said cell at the instant τ.

For any cell, it is also possible to provide for the determination of said threshold on the basis of an error on the amount of charge discharged for said cell during an interval, said error being calculated using the following expression:

δΔqᵢ(T)=|T·δI_{bal}|

where “T” represents said interval,

“δΔqᵢ(T)” represents the error on the amount of charge discharged for said cell during said interval, and

“δI_{bal}” represents the error on the balancing current of the cells of the electric storage battery.

As explained below, these error calculations allow for most of the inaccuracies encountered in an electric storage battery. In this way, the calculation of the threshold is refined, and therefore the reliability of the detection of the self-discharge defect is improved.

Other objects, characteristics and advantages of the invention will be apparent from the following description, provided solely by way of non-limiting example, with reference to the attached drawings, in which:

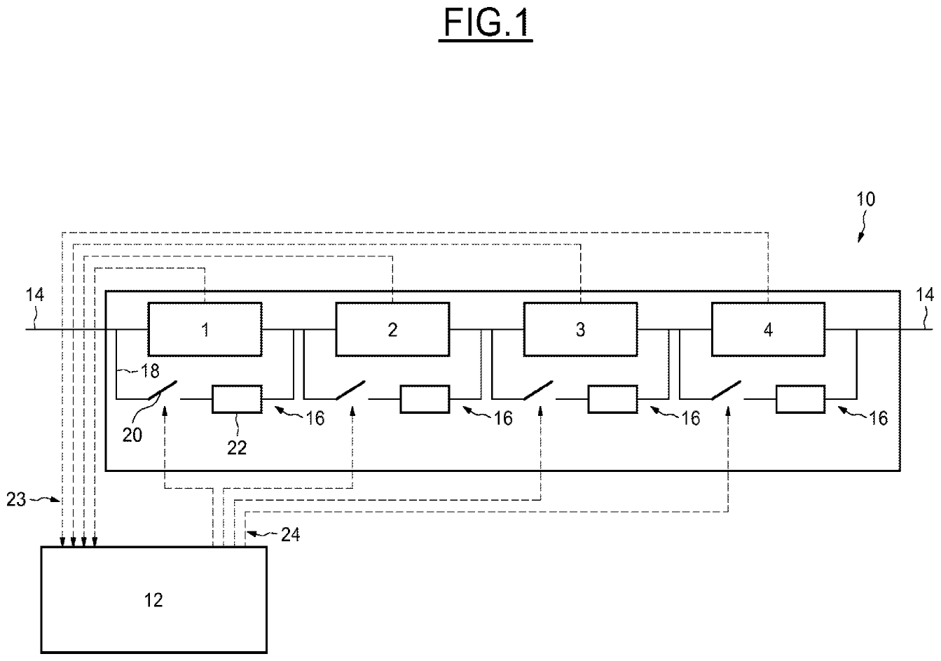

FIG. 1 shows schematically an electric storage battery,

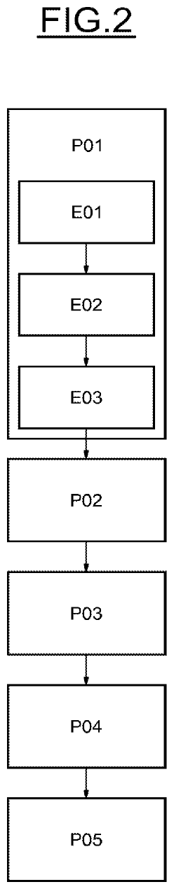

FIG. 2 shows schematically a detection method according to an exemplary embodiment of the invention;

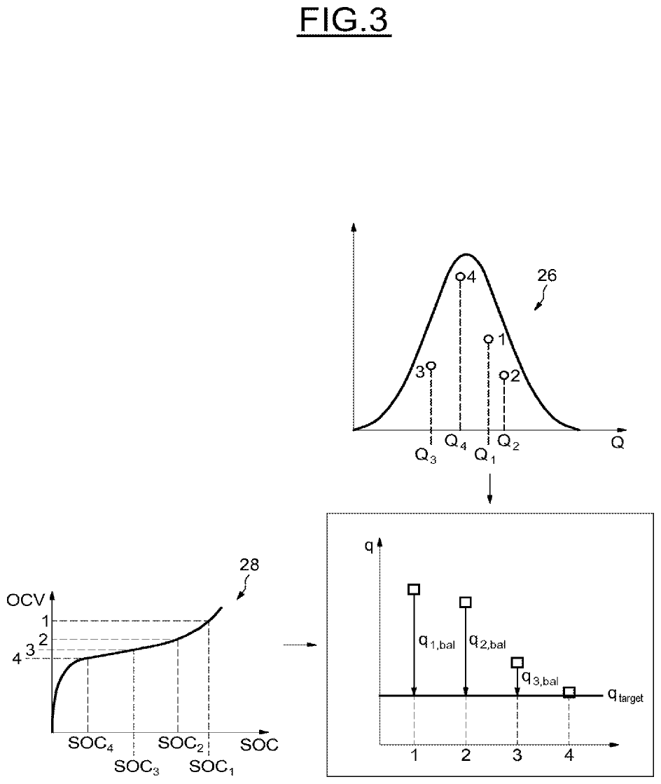

FIG. 3 shows three graphs illustrating the calculation of the charges to be balanced for a cell of the battery of FIG. 1,

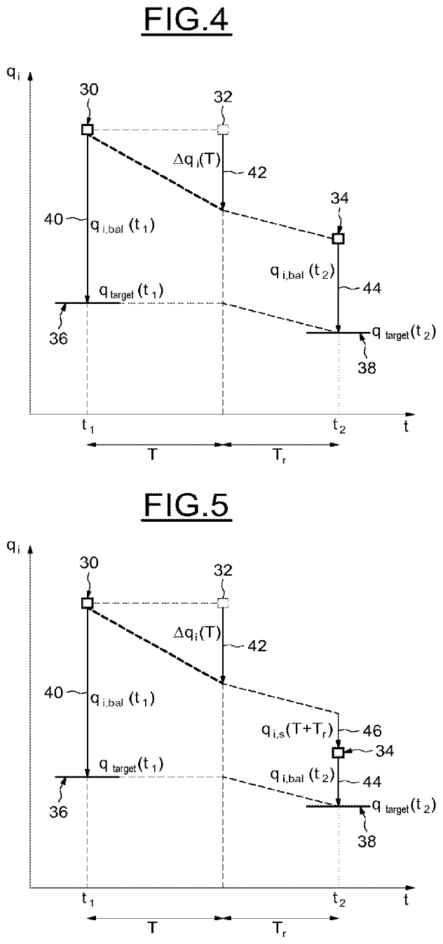

FIG. 4 shows a graph illustrating the charge balance during a balancing and a relaxation of a cell of the battery of FIG. 1 according to a first case of operation, and

FIG. 5 shows a graph illustrating the charge balance during a balancing and a relaxation of a cell of the battery of FIG. 1 according to a second case of operation.

With reference to FIG. 1, an electric storage battery 10 is shown schematically. The battery 10 is designed to be incorporated into an electrically propelled automotive vehicle for supplying an electrical traction machine belonging to the powertrain of the automotive vehicle.

The battery 10 comprises two terminals 14. The battery 10 comprises four battery cells, denoted 1, 2, 3 and 4 respectively. In the illustrated example, the cells 1, 2, 3 and 4 are connected in series. However, it would be feasible to have cells connected in parallel, or alternatively some of the cells connected in parallel and the rest of the cells connected in series, without thereby departing from the scope of the invention. Similarly, it would clearly be feasible to have a different number of cells without departing from the scope of the invention.

The battery 10 has an information connection to a management system 12. The management system 12 is also known by the English expression “battery management system” or by the abbreviation “BMS”. The system 12 manages various methods used during the life of the battery 10. For example, as explained below, the management system 12 manages a method of balancing the cells of the battery 10.

Each of the cells 1, 2, 3, 4 is associated with a respective balancing circuit 16. In the illustrated example, the balancing circuits 16 are identical for all the cells of the battery 10. For any cell 1, 2, 3 or 4, the balancing circuit 16 associated with this cell comprises an electrical circuit 18 connected to the two terminals of this cell. In the electrical circuit 18, a switch 20 and a balancing resistance 22 are connected in series. However, the invention is not limited to this form of the balancing circuit. In particular, it would also be feasible to have a single balancing circuit common to all the cells of the battery 10 and capable of executing the balancing of any one of the cells separately.

The system 12 is provided with hardware and software means for receiving data relating to the cells 1, 2, 3 and 4, as represented by the arrows in broken lines 23. The system 12 is provided with hardware and software means for determining, on the basis of the received data, intermediate data relating to the cells 1, 2, 3 and 4.

For example, for any cell i chosen from among the cells 1, 2, 3, and 4, the system 12 is capable of receiving the voltage vᵢ at the terminals of the cell i and the current I_{i,bal} flowing through the cell i during the balancing of this cell i. The system 12 is capable of determining the zero current voltage OCVᵢ of the cell i, also known by the English expression “open circuit voltage”, and the state of charge SOCᵢ of the cell i, also known by the English expression “state of charge”.

As represented by the arrows in broken lines 24, the system 12 is provided with hardware and software means for causing the opening and closing of the switches 20 associated with the cells 1, 2, 3 and 4 respectively. Consequently, for any cell i, where i is in the range from 1 to 4, if the system 12 considers that the balancing of the cell i must be carried out, it causes the closing of the switch 20 of the balancing circuit 16 corresponding to the cell i. Electrical energy released by the cell i is dissipated in the balancing resistance 22 of the balancing circuit 16 associated with the cell i. If the management system 4 considers that the balancing of the cell i must be halted, it causes the opening of the switch 20 of the balancing circuit 16 associated with the cell i.

The execution of a method of detecting a self-discharge defect according to the invention will now be described with reference to FIGS. 2 to 5. The method is executed in order to detect a self-discharge defect in the cells 1, 2, 3 and 4 of the battery 10, using the management system 12. An example of the execution of the method according to the invention is illustrated schematically in FIG. 2.

The method according to the invention comprises a first phase P01 of balancing the charges of the cells of the battery 10. In the description of phase P01, reference may be made to FIG. 3, which shows a first graph 26 of the distribution of the capacities Q₁, Q₂, Q₃ and Q₄ of the respective cells 1, 2, 3 and 4. The capacities are shown in a Gaussian curve distribution. FIG. 3 contains a second graph 28 illustrating the relationship between the zero current voltage OCV of the cells 1, 2, 3 and 4 as a function of the state of charge SOC of said cells.

Phase P01 comprises a first step E01 in which the target parameters are determined. More precisely, a target state of charge SOC_{target} and a target capacity Q_{target} are determined. In the illustrated example, the target state of charge SOC_{target} and the target capacity Q_{target} are defined as the state of charge SOCᵢ and the capacity Qᵢ of the cell i having the lowest state of charge. In the case of FIG. 3, the target state of charge SOC_{target} corresponds to the state of charge SOC₄ of the cell 4, and the target capacity Q_{target} is defined as equal to the capacity Q₄ of the cell 4:

$$[ \begin{matrix}{SOC}_{target} = {SOC}_{4} \\ {Q}_{target} = {Q}_{4}\end{matrix} \qquad ( 1 )$$

Phase P01 comprises a second step E02 in which the projected charge to be balanced for the cells of the battery 10 is calculated. For any cell i, the projected charge to be balanced q_{i,bal} for the cell i corresponds to the charge that must be discharged into the resistance 22 of the balancing circuit 16 associated with the cell i in order to balance the cell i with respect to the target cell. For this purpose, the following equation may be applied:

q_{i,bal}=SOCᵢ×Qᵢ−SOC_{target}×Q_{target} (2)

In the illustrated example, it is advantageously assumed that there is no dispersion among the capacities of the cells of the battery 10. Therefore, if Q denotes the capacity of all the cells, the charge q_{i,bal} may be calculated by applying the equation:

q_{i,bal}=(SOCᵢ−SOC_{target})×Q (3)

The method according to the invention is not limited to the calculation described above by way of example. In a first example of a variant, for any cell i, the charge q_{i,bal} may be calculated without departing from the scope of the invention, by applying the equation

q_{i,bal}=ƒ(OCVᵢ)×(SOHᵢ×Q_{i,nom})−ƒ(OCV_{target})×(SOH_{target}×Q_{target,nom}) (4)

In this equation, the function ƒ denotes the function whose graphic representation corresponds to graph 28 of FIG. 3, SOHᵢ denotes the state of health of the cell i, also known by the English term “state of health”, Q_{i,nom} denotes the nominal capacity of the cell i, SOH_{target} denotes the target state of health, and Q_{target,nom} denotes the target nominal capacity. For example, the target state of health SOH_{target} and the target nominal capacity Q_{target,nom} are, respectively, the state of health and the nominal capacity of the target cell, in this case the state of health SOH₄ and the nominal capacity Q_{4,nom} of the cell 4.

The equation according to the first example of a variant may, notably, be used if the management system 12 is provided with means for determining the states of health of each of the cells 1 to 4 individually.

According to a second example of a variant of the method according to the invention, a different way of determining the target state of charge SOC_{target} may be chosen. For example, the target state of charge SOC_{target} may be the mean of the states of charge of the cells of the battery 10. This may cause the projected charge to be balanced, q_{i,bal} of a cell i to take negative values. However, since the balancing system is dissipative, it is impossible to recharge the corresponding cell. In such a case, therefore, for any cell i, the projected charge to be balanced q_{i,bal} is automatically defined as equal to zero when the calculation of this charge gives a negative result.

The projected charges to be balanced, q_{1,bal}, q_{2,bal}, q_{3,bal} and q_{4,bal}, of the respective cells 1, 2, 3 and 4 are shown schematically on the third graph 30 of FIG. 3. Graph 30 shows, for each cell i chosen from among the cells 1, 2, 3 and 4, the charge qᵢ of said cell and the charge of the target cell, in this case q₄. For each cell i, where i is in the range from 1 to 4, the projected charge to be balanced q_{i,bal} is represented schematically by a downward-pointing vertical arrow. As shown on graph 30, the projected charge to be balanced q_{4,bal} of the target cell 4 is equal to zero.

Phase P01 comprises a third step E03 in which the balancing of the cells of the battery 10 is carried out. For this purpose, the system 12 causes the closing of the switch 20 associated with each of the cells that are to be balanced. Simultaneously, at each instant t and for every cell i of the battery 10, the system 12 calculates the amount of charge actually discharged Δqᵢ(t) for the cell i at the instant t. For any cell i of the battery 10, the amount of charge actually discharged by the cell i at an instant t may be calculated according to the expression:

Δqᵢ(t)=∫₀^{t}I_{i,bal}(τ)dτ (5)

Now, Ohm's law states that:

$${I}_{i , bal} ( t ) = \frac{{v}_{i} ( t )}{{R}_{bal}} \qquad ( 6 )$$

where R_{bal} is the value of the resistance 22 of the balancing circuits 16.

The amount Δqᵢ(t) can therefore be calculated by applying the equation:

$$Δ {q}_{i} ( t ) = \frac{1}{{R}_{bal}} {\int }_{0}^{t} {v}_{i} ( τ ) d τ \qquad ( 7 )$$

For any cell i of the battery 10, the system 12 constantly compares the projected charge to be balanced q_{i,bal} with the amount of charge actually discharged Δqᵢ(t). As long as the projected charge to be balanced q_{i,bal} is strictly greater than the amount of charge actually discharged Δqᵢ(t), the switch 20 remains closed. If the charge q_{i,bal} becomes equal to or greater than the amount Δqᵢ(t), the switch 20 associated with the cell i is opened. The balancing of the cell i is then terminated.

Since the projected charge to be balanced q_{4,bal} for the cell 4 is zero, it is impossible for the amount of charge actually discharged Δq₄(t) by this cell to be strictly less than the projected charge to be balanced at any instant t. Consequently, in the illustrated example, the switch 20 associated with the cell 4 is not closed during the step E03.

According to a third example of a variant of the method according to the invention, the balancing may be controlled on the basis of a calculated balancing time. In step E02 of this example of a variant of the method, for any cell i of the battery 10, the projected charge to be balanced q_{i,bal} for the cell i is used to calculate a balancing time t_{i,bal} for the cell i. This balancing time t_{i,bal} for the cell i is calculated by applying the equation:

$$\begin{matrix}{t}_{i , bal} = \frac{{q}_{i , bal}}{{I}_{i , bal}} & ( 8 ) \\ where & \\ {I}_{i , bal} = \frac{{v}_{nom}}{{R}_{bal}} & ( 9 )\end{matrix}$$

where Vₙₒₘ is the nominal voltage of the cells of the battery 10. In the third example of a variant, the dispersion of the balancing resistance and the nominal voltage of the cells is assumed to be zero. Thus the balancing current I_{i,bal} is assumed to be identical for all the cells and is denoted I_{bal}.

In view of the above, for any cell i of the battery 10, the balancing time t_{i,bal} may be calculated by applying the formula:

$${t}_{i , bal} = \frac{{q}_{i , bal}}{{I}_{bal}} \qquad ( 10 )$$

In step E03 of the third example of a variant, for any cell i of the battery 10, the system 12 sets the switch 20 associated with the cell i to a closed state between the instants t₁ and t₁+t_{i,bal}, where t₁ is the instant of the start of balancing.

The third example of a variant is advantageous in that there is no need to constantly calculate the amount Δqᵢ(t) for all the cells. The requirements in terms of calculation resources are therefore reduced. However, the balancing becomes more approximate, because the nominal voltage of the cells, which is constant, is used in the calculation of the balancing time in place of the actual voltage which varies during the use of the battery 10.

In a fourth example of a variant, the amount of charge actually discharged Δqᵢ(t) by a cell i at an instant t can be calculated in a different way. In this fourth example of a variant, for any cell i, the amount Δqᵢ(t) is calculated by applying the equation:

Δqᵢ(T)=I_{bal}×t_{i,bal} (11)

As a general rule, balancing is possible only during the mission of the vehicle, that is to say when the vehicle is travelling and under control. The balancing time is then often too short to allow a balancing of all the cells in a single mission. In this case, the balancing is interrupted and resumes after a period of interruption.

In the exemplary embodiment illustrated, the target parameters are updated when balancing is resumed after an interruption. This choice is advantageous, notably, because the cells may be in a high state of charge when the balancing is resumed.

However, the invention is not limited to this choice, and it would be feasible for there to be a fifth example of a variant in which, when the balancing is resumed after an interruption, the target parameters are not updated. This fifth example is advantageous in that it requires fewer calculation resources.

The method of detection according to the invention then comprises, for each cell of the battery 10, a phase P02 of relaxation of the cell. During phase P02, the current of the cell is kept equal to zero during a relaxation time Tᵣ.

In the illustrated exemplary embodiment, the relaxation time Tᵣ is calculated on the basis of the balancing time t_{i,bal} of the cells of the battery 10. More precisely, the time Tᵣ is substantially equal to the mean of the balancing times t_{i,bal} of the cells of the battery 10 multiplied by a coefficient in the range from 0.5 to 1.

FIG. 4 shows the variation of the charge over time in a cell i of the battery 10 undergoing the phases of balancing P01 and relaxation P02 of the method according to the invention. Cell i, in which the variation of the charge is shown in FIG. 4, is not subject to any loss of charge due to a self-discharge defect.

The balancing starts at an instant t₁ and is interrupted after the expiry of a balancing period T. The period T may be less than or equal to the balancing time t_{i,bal} calculated for the cell i. If the balancing is interrupted, a relaxation of the cell i is carried out up to an instant t₂.

A square 32 shows schematically the charge qᵢ(t₁) of the cell i at the instant t₁. A square 34 illustrates the charge qᵢ(t₂) of the cell i at the instant t₂. A horizontal line 36 represents the charge a (t) of the target cell at the instant t₁. A horizontal line 38 represents the charge a (t) of the target cell at the instant t₂. A first vertical downward arrow 40 represents the projected charge to be balanced q_{i,bal}(t₁) for the cell i estimated at the instant t₁. A second vertical downward arrow 42 represents the amount of charge actually discharged Δqᵢ(T) for the cell i during the balancing. A third vertical downward arrow 44 shows schematically the projected charge to be balanced q_{i,bal}(t₂) for the cell i estimated at the instant t₂.

As mentioned above, the cell i in the case of FIG. 4 does not exhibit any self-discharge defect. The data relating to the charge of the cell i therefore conform to the following equation:

q_{i,bal}(t₂)=q_{i,bal}(t₁)−Δqᵢ(T) (12)

FIG. 5 shows the variation of the charge over time in a cell i undergoing the same phases of balancing P01 and relaxation P02 as in FIG. 4. The cell i, the variation of the charge of which is shown in FIG. 5, is subject to losses of charge due to a significant self-discharge defect.

As in FIG. 4, the balancing starts at an instant t₁ and is interrupted after the expiry of a balancing period T, the cell i then being relaxed until an instant t₂.

The graph of FIG. 5 differs from that of FIG. 4 in that a fourth vertical downward arrow 46 shows schematically the amount of charge discharged due to the self-discharge Δq_{i,s}(T+Tᵣ) of the cell i during the phases P01 and P02 of the method according to the invention.

Since the cell i in the case of FIG. 5 exhibits a self-discharge defect, the data relating to its charge cannot conform to equation (12). Instead, the data relating to the charge of the cell i in the case of FIG. 5 conform to the equation:

q_{i,bal}(t₂)=q_{i,bal}(t₁)−Δqᵢ(T)−Δq_{i,s}(T+Tᵣ) (13)

In an extreme case, in which the cell i exhibits a very large self-discharge defect, or in which the balancing interval T and/or the relaxation interval Tᵣ is very large, the amount of charge discharged between the instants t₁ and t₂ may possibly be greater than the projected charge to be discharged q_{i,bal}(t₁) by the cell i calculated at the instant t₁. In this case,

q_{i,bal}(t₁)−Δqᵢ(T)−Δq_{i,s}(T+Tᵣ)<0 (14)

In view of the above, for any cell i of the battery 10, a self-discharge defect of the cell i may be detected by calculating the charge balance Σᵢ for the cell i by applying the following equation:

Σᵢ=q_{i,bal}(t₂)+Δqᵢ(T)−q_{i,bal}(t₁) (15)

In a theoretical model, for any cell i of the battery 10, there is no self-discharge defect of the cell i if the charge balance Σᵢ is zero.

Conversely, for any cell i of the battery 10, there is a self-discharge defect of the cell i if a strictly positive balance Σᵢ has been calculated. In this case, the amount of charge discharged due to the self-discharge Δq_{i,s}(T+Tᵣ) of the cell i may be calculated by applying the equation:

q_{i,s}(T+Tᵣ)=q_{i,bal}(t₁)−q_{i,bal}(t₂)−qᵢ(T) (16)

The self-discharge current I_{i,s} of the cell i may be estimated by applying the equation:

$${I}_{i , s} = \frac{{q}_{i , s} ( T + {T}_{r} )}{T + {T}_{r}} \qquad ( 17 )$$

A theoretical model for detecting the presence of a self-discharge defect in a cell i of the battery 10 by calculating the charge balance Σᵢ has been shown in the preceding text. However, this model is not applicable to the target cell. Another calculation used to detect a self-discharge defect in the target cell will now be detailed.

For this calculation, it is necessary to detect whether the target cell is discharged more rapidly in the course of the detection method than the other cells of the battery 10. More precisely, for any cell i of the battery 10, where the cell i is other than the target cell, if

qᵢ(t₂)>qᵢ(t₁), where qᵢ(T)≠0 (18)

then a self-discharge defect is detected in the target cell.

Thus the theoretical model shown above can be used to detect a self-discharge defect in any of the cells of the battery 10. In practice, however, a threshold must be applied to achieve effective detection, in order to allow for all the sources of inaccuracy which would prevent detection or which, conversely, would result in false detection.

In particular, for any cell i of the battery 10, inaccuracies may occur in the calculation of the projected charge to be balanced q_{i,bal} for the cell i. These inaccuracies may arise from the following elements, among others:
the voltage sensor measuring the zero current voltage OCVᵢ,
an insufficient relaxation time before the measurement of the zero current voltage OCVᵢ,
the approximations of the map containing the values of the state of charge SOCᵢ as a function of the voltage OCVᵢ,
the approximations in ascertaining the state of health SOHᵢ which can only be estimated by means of a calculation or a mathematical model,
discrepancies in the tolerance of the capacity Qᵢ at the factory gate.

In the calculations, allowance must be made for the aforesaid inaccuracies, not only for magnitudes relating to the cell i but also for magnitudes relating to the target cell.

Other inaccuracies may occur in the calculation of the amount of charge actually discharged Δqᵢ(T) by the cell i during the relaxation interval T.

According to the illustrated example, for any cell i of the battery 10, the amount of charge actually discharged Δqᵢ(t) is given by the equation:

$$Δ {q}_{i} ( t ) = \frac{1}{{R}_{bal}} {\int }_{0}^{t} {v}_{i} ( τ ) d τ \qquad ( 7 )$$

In this case, the origins of the inaccuracies comprise, notably:
the variability of the resistance R_{bal}, which may change with the temperature,
the voltage sensor measuring the voltage at the terminals of the cell i.

For any cell i of the battery 10, the amount of charge actually discharged Δqᵢ(t) may also be found by the equation:

Δqᵢ(T)=I_{bal}×t_{i,bal} (11)

In this case, the origins of the inaccuracies comprise, in particular, the difference between the balancing current I_{bal} measured by a current sensor and assumed to be equal for all the cells, and the true balancing current I_{i,bal} flowing through the cell i.

In view of the above, in the illustrated example, for any cell i, a threshold εₜ combining all the inaccuracies mentioned above is defined. In order to calculate the threshold εₜ, the procedure for calculating the error δq_{i,bal} on the projected charge to be balanced for the cell i and the error δΔqᵢ(T) on the amount of charge actually discharged for the cell i is detailed. For any cell i of the battery 10, on the basis of the equation:

q_{i,bal}=SOCᵢ×Qᵢ−SOC_{target}×Q_{target} (2)

the first-order differential of the projected charge to be balanced for the cell i can be developed:

$${dq}_{i , bal} = \frac{\partial }{\partial {SOC}_{i}} ( {SOC}_{i} \times {Q}_{i} ) {dSOC}_{i} + \frac{\partial }{\partial {Q}_{i}} ( {SOC}_{i} \times {Q}_{i} ) {dQ}_{i} + \frac{\partial }{\partial {SOC}_{target}} ( - {SOC}_{target} \times {Q}_{target} ) {dSOC}_{target} + \frac{\partial }{δ {Q}_{target}} ( - {SOC}_{target} \times {Q}_{target} ) {dQ}_{target} \qquad ( 19 )$$

This equation may be simplified as follows:

dq_{i,bal}=QᵢdSOCᵢ+SOCᵢdQᵢ−Q_{target}dSOC_{target}−SOC_{target}dQ_{target} (20)

For any cell i of the battery 10, the error δq_{i,bal} on the projected charge to be balanced for the cell i is thus calculated as follows:

δq_{i,bal}=|Qᵢ·δSOCᵢ|+|SOCᵢ·δQᵢ|+Q_{target}·δSOC_{target}|+|SOC_{target}·δQ_{target}| (21)

where δSOCᵢ denotes the error on the state of charge of the cell i, δQᵢ denotes the error on the capacitance of the cell i, δSOC_{target} denotes the error on the state of charge of the target cell, and δQ_{target} denotes the error on the capacity of the target cell.

The above equation for calculating the error δq_{i,bal} is valid for the instants t₁ and t₂. For example, for any cell i of the battery 10, an error of 3% on the state of charge SOCᵢ estimated in a general manner is equivalent to replacing the occurrences of δSOCᵢ with 0.03. The same applies to the occurrences δQᵢ.

To obtain an even more accurate calculation of the error δq_{i,bal}, the errors δQᵢ and δSOCᵢ can be analyzed further, using the equation:

q_{i,bal}=f(OCV₁)×(SOHᵢ×Q_{i,nom})−f(OCV_{target})×(SOH_{target}×Q_{target,nom}) (4)

In this case, for any cell i of the battery 10, the state of charge SOCᵢ being calculated after the relaxation of the cell i on the basis of the zero current voltage, the error δSOCᵢ arises from:
an insufficient relaxation time before the measurement of the zero current voltage OCVᵢ,
the voltage sensor measuring the zero current voltage OCVᵢ,
the approximations of the map containing the values of the state of charge SOCᵢ as a function of the voltage OCVᵢ, for which the sensitivity dOCV/dSOC changes as a as a function of the voltage OCVᵢ, since it is a nonlinear function.

Regarding the error δΔqᵢ(T) on the amount of charge actually discharged, for any cell i of the battery 10 the amount Δqᵢ(T) may be found by the equation:

$$Δ {q}_{i} ( t ) = \frac{1}{{R}_{bal}} {\int }_{0}^{t} {v}_{i} ( τ ) d τ \qquad ( 7 )$$

On the basis of this expression, the first-order differential of the amount of charge actually discharged for the cell i can be developed:

$$d Δ {q}_{i} ( T ) = \frac{\partial Δ {q}_{i} ( T )}{\partial {R}_{bal}} {dR}_{bal} + \frac{\partial Δ {q}_{i} ( T )}{\partial ϒ} d ϒ , \\ where ϒ {=}^{Δ} {\int }_{0}^{T} {v}_{i} ( τ ) d τ \qquad ( 22 )$$

This equation may be simplified as follows:

$$d Δ {q}_{i} ( T ) = \frac{- 1}{{R}_{bal}^{2}} ϒ {dR}_{bal} + \frac{1}{{R}_{bal}} d ϒ \qquad ( 23 )$$

For any cell i of the battery 10, the error δΔqᵢ(T) on the amount of charge actually discharged for the cell i is thus calculated as follows:

$$δΔ {q}_{i} ( T ) = \vert \frac{1}{{R}_{bal}^{2}} ϒ \cdot δ {R}_{bal} \vert + \vert \frac{1}{{R}_{bal}} \cdot δϒ \vert \qquad ( 24 )$$

where δR_{bal} denotes the error on the balancing resistance R_{bal} and δY denotes the error on the voltage at the terminals of the cell i.

The error δY on the voltage at the terminals of the cell i is essentially a white noise. Therefore, in the illustrated exemplary embodiment, the error δY is assumed to be equal to zero. The amount Δqᵢ(T) may also be found by the equation:

Δqⱼ(T)=I_{bal}×t_{i,bal} (11)

By developing the first-order differential we obtain:

$$d Δ {q}_{i} ( T ) = \frac{\partial Δ {q}_{i} ( T )}{\partial {I}_{bal}} {dI}_{bal} + \frac{\partial Δ {q}_{i} ( T )}{\partial T} d T \qquad ( 25 )$$

For any cell i of the battery 10, the error Δqᵢ(T) on the amount of charge actually discharged for the cell i may then be calculated as follows:

Δqᵢ(T)=|T·I_{bal}|+|I_{bal}·T| (26)

where I_{bal} denotes the error on the balancing current and T denotes the error on the balancing time.

The error T may normally be considered to be zero, because it is negligible.

In view of the above, for any cell i of the battery 10, the error Δqᵢ(T) may be calculated by applying one of the two simplified equations below:

$$\begin{matrix}δΔ {q}_{i} ( T ) = \vert \frac{1}{{R}_{bal}^{2}} ϒ \cdot δ {R}_{bal} \vert and & ( 27 ) \\ δΔ {q}_{i} ( T ) = \vert T \cdot δ {I}_{bal} \vert & ( 28 )\end{matrix}$$

For any cell i of the battery 10, on the basis of the equation:

Σᵢ=q_{i,bal}(t₂)+Δqᵢ(T)−q_{i,bal}(t₁) (15)

it is possible to write the equation for the calculation of the balance Σᵢ, allowing for the errors described above:

Σᵢ=(q_{i,bal}(t₂)±δq_{i,bal}(t₂))+(Δqᵢ(T)±δΔqᵢ(T))−(q_{i,bal}(t₁)±δq_{i,bal}(t₁)) (29)

The equation (29) may also be written thus:

Σᵢ=(q_{i,bal}(t₂)+Δqᵢ(T)−q_{i,bal}(t₁))=(δq_{i,bal}(t₂)+δΔqᵢ(T)+δq_{i,bal}(t₁)) (30)

The threshold ε must therefore be defined as follows:

ε=δq_{i,bal}(t₂)+δΔqᵢ(T)+δq_{i,bal}(t₁) (31)

using the previously written expressions for the errors δq_{i,bal}(t₁), δq_{i,bal}(t₂) and δΔqᵢ(T).

Thus a way of detecting a self-discharge defect in any of the cells of the battery 10 has now been described in theory and in practice. With reference to FIG. 2, the method according to the invention comprises a third phase P03 of calculating the charge balance Σᵢ using the equation (15), and a fourth phase P04 of calculating the threshold εᵢ by using the equations (31), (21), (27) and (28). Finally, the method comprises a fifth phase P05 of comparing the balance Σᵢ with the threshold εᵢ. If, in phase P05, the balance Σᵢ is greater than or equal to the threshold εᵢ for any cell i, then a self-discharge defect for the cell i is detected. Additionally, during the phase P05, the aforementioned test is carried out to detect whether the target cell has a self-discharge defect, by observing whether the condition of equation (18) is met.

By using the threshold calculated in this way, it is possible to avoid the non-detection of a self-discharge defect and the false detection of a non-existent self-discharge defect. In particular, the threshold εᵢ is adapted to allow for most of the inaccuracies affecting the cells of an electric storage battery, particularly one of the type incorporating an electrically-propelled automotive vehicle. In this way, the reliability of the detection method according to the invention is maximized.

In general terms, the method according to the invention may be used to detect a self-discharge defect in a cell of the battery at an early stage without adding any hardware device, simply by making software modifications.

In particular, the method according to the invention does not require the comparison of the states of charge of the cells after a long relaxation period. The method according to the invention thus enables the detection of a self-discharge defect to be accelerated, so that this detection may be carried out more frequently and therefore at an earlier stage.

1-10. (canceled)

11. A method for detecting, in an electric storage battery having a plurality of battery cells, a self-discharge defect in a cell, wherein:
a balancing of the charges of the battery cells is carried out, at least partially,
a relaxation of the battery cells is carried out,
for each battery cell (i), a charge balance during the balancing and relaxation (Σᵢ) of said cell (i) is calculated, and
the possible existence of any self-discharge defect of said cell (i) is detected for each battery cell (i) on the basis of the charge balance during the balancing and relaxation (Σᵢ) calculated for said cell (i).

12. The method as claimed in claim 11, wherein, for each battery cell (i), the charge balance during the balancing and relaxation (Σᵢ) of said cell (i) is calculated with allowance for at least one magnitude chosen from among the charge to be balanced (q_{i,bal}(t₁)) for said cell (i) immediately before the start of the balancing of said cell (i), the charge to be balanced (q_{i,bal}(t₂)) for said cell (i) immediately after the end of the relaxation of said cell (i), and the amount of charge discharged (Δqᵢ(T)) for said cell (i) during the balancing.

13. The method as claimed in claim 12, wherein, for any battery cell (i), the charge balance during the balancing and relaxation (Σᵢ) of said cell (i) is calculated by applying the following relationship:
Σᵢ=q_{i,bal}(t₂)+Δqᵢ(T)−q_{i,bal}(t₁)
where “Σ_{I}” denotes the charge balance during the balancing and relaxation of said cell (i),
“q_{i,bal}(t)” denotes the charge to be balanced for said cell (i) at an instant t,
“Δqᵢ(T)” denotes the amount of charge discharged for said cell (i) during an interval T,
“t₁” denotes an instant located immediately before the start of the balancing of said cell (i),
“t₂” denotes an instant located immediately after the end of the relaxation of said cell (i), and
“T” denotes the period during which the balancing of the charges of the cell (i) has been executed.

14. The method as claimed in claim 11, wherein, for each cell (i), the balancing comprises a step of calculating a charge to be balanced (q_{i,bal}) for said cell and a step of executing the balancing in which the amount of charge discharged (Δqᵢ(t)) for said cell (i) is calculated, and the balancing step is continued as long as the charge to be balanced (q_{i,bal}) for said cell (i) is strictly greater than the amount of charge discharged (Δqᵢ(t)) for said cell (i).

15. The method as claimed in claim 11, wherein, for each cell (i), the balancing comprises a step of calculating a charge to be balanced (q_{i,bal}) for said cell (i) and a step of calculating a balancing time (t_{i,bal}) of said cell (i) on the basis of the calculated charge to be balanced (q_{i,bal}) for said cell (i), in which the balancing is executed during the calculated balancing time (t_{i,bal}).

16. The method as claimed in claim 11, wherein, for each cell (i), a charge to be balanced (q_{i,bal}) for said cell is calculated on the basis of a parameter chosen from among a state of charge (SOC) of said cell (i), a state of charge (SOC_{target}) of a target cell, a capacity (Q) of said cell (i), a capacity (Q_{target}) of a target cell, a state of health (SOHᵢ) of said cell (i), a state of health (SOH_{target}) of a target cell, a zero current voltage (OCVᵢ) of said cell (i), a zero current voltage (OCV_{target}) of a target cell, a nominal capacity (Q_{i,nom}) of said cell (i) and a nominal capacity (Q_{target,nom}) of a target cell, and/or wherein, for each cell (i), an amount of charge discharged (Δqᵢ(T)) during a period (T) for said cell (i) is calculated on the basis of at least one parameter chosen from among a balancing resistance (R_{bal}), a voltage (vᵢ(t)) at the terminals of said cell (i) at an instant (t) belonging to said period (T), a balancing current (I_{bal}) of the cells of the electric storage battery, and a nominal voltage (Vₙₒₘ) of the cells of the electric storage battery.

17. The method as claimed in claim 11, wherein the possible presence of a self-discharge defect in a first battery cell is detected if, for any second battery cell (i) other than the first battery cell, the charge to be balanced al (q_{i,bal}(t₂)) by said second cell (i) immediately after the end of the relaxation of said second cell (i) is strictly greater than the charge to be balanced (q_{i,bal}(t₁)) by said second cell (i) immediately before the start of the balancing of said second cell (i), and the amount of charge discharged (Δqᵢ(T)) by said second cell (i) during the balancing and relaxation is other than zero.

18. The method as claimed in claim 11, wherein, for each cell (i), the possible presence of a self-discharge defect in said cell (i) is detected if the calculated charge balance for said cell during the balancing and relaxation (Σᵢ) exceeds a strictly positive threshold (ε₁), said threshold (ε₁) being determined on the basis of at least one error chosen from among an error on the charge to be balanced (δq_{i,bal}(t₁)) for said cell (i) immediately before the start of the balancing of said cell (i), an error on the charge to be balanced (δq_{i,bal}(t₂)) for said cell (i) immediately after the end of the relaxation of said cell (i), and an error on the amount of charge discharged (δΔqᵢ(T)) for said cell (i) during the balancing and relaxation.

19. The method as claimed in claim 18, wherein, for any cell (i), said threshold (εᵢ) is determined on the basis of an error on the charge to be balanced (δq_{i,bal}) for said cell (i), said error (δq_{i,bal}) being calculated, for any instant (t), according to the following expression:
δq_{i,bal}=|Qᵢ·δSOCᵢ|+|SOCᵢ·δQᵢ|+|Q_{target}·δSOC_{target}|+|SOC_{target}·δQ_{target}|

where “δq_{i,bal}” represents the error on the charge to be balanced by said cell (i) at said instant,
“δSOCᵢ” represents the error on the state of charge of said cell (i),
“δQᵢ” represents the error on the charge of said cell (i),
“δSOCᵢ” represents the state of charge of said cell (i) at said instant (t),
“Qᵢ” represents the charge of said cell (i) at said instant (t),
“δSOC_{target}” represents the error on the state of charge of the target cell,
“δQ_{target}” represents the error on the charge of the target cell,
“SOC_{target}” represents the state of charge of the target cell at said instant (t), and
“Q_{target}” represents the charge of the target cell at said instant (t).

20. The method as claimed in claim 18, wherein, for any cell (i), said threshold is determined on the basis of an error on the amount of charge discharged (δΔqᵢ(T)) for said cell (i) during an interval (T), said error (δΔqᵢ(T)) being calculated by using at least one of the following expressions:
$$δΔ {q}_{i} ( T ) = \vert \frac{1}{{R}_{bal}^{2}} \cdot {\int }_{0}^{T} {V}_{i} ( τ ) d τ \cdot δ {R}_{bal} \vert and δΔ {q}_{i} ( T ) = \vert T \cdot δ {I}_{bal} \vert$$
where “T” represents said interval,
“δΔqᵢ(T)” represents the error on the amount of charge discharged for said cell (i) during said interval (T),
“R_{bal}” represents the resistance used for the balancing,
for any instant t belonging to said interval, “Vᵢ(τ)” denotes the voltage measured at the terminals of said cell (i) at the instant τ, and
“δI_{bal}” represents the permitted deviation of the balancing current of the cells of the electric storage battery.
